(19) United States
(12) Patent Application Publication
(10) Pub. No.: US 2026/0173737 A1
(43) Pub. Date: Jun. 18, 2026

(54) DISPLAY DEVICE

(71) Applicant: LG DISPLAY CO., LTD., SEOUL (KR)

(72) Inventors: SeoHyun Nam, Paju-si (KR); YoungNam Lim, Paju-si (KR)

(21) Appl. No.: 19/194,334

(22) Filed: Apr. 30, 2025

(30) Foreign Application Priority Data
Dec. 17, 2024 (KR) 10-2024-0189160

(51) Int. Cl. H10K 59/80; H10K 59/122

(52) U.S. Cl. CPC H10K 59/879; H10K 59/122; H10K 59/80515; H10K 59/80518; H10K 59/873

(57) ABSTRACT

A display device includes a first planarization layer, and a second planarization layer on the first planarization layer and having a first opening, a first pixel electrode in a first subpixel among a plurality of subpixels, disposed on the first planarization layer in the first opening, and extending along a side surface of the second planarization layer, a bank on the first pixel electrode, having an upper surface and an inclined side surface, overlapping a portion of the first pixel electrode and the first opening, and including a first hole having a smaller size than the first opening, a first light emitting layer on the first pixel electrode, a common electrode on the first light emitting layer and extending onto the bank, and nano-structures positioned in a first subpixel area of the first subpixel or a surrounding area of the first subpixel and disposed on the common electrode.

### CROSS REFERENCE TO RELATED APPLICATION

Pursuant to 35 U.S.C. § 119(a), this application claims the benefit of an earlier filing date and right of priority to Korean Patent Application No. 10-2024-0189160, filed on Dec. 17, 2024, the contents of which are hereby incorporated by reference in their entirety.

### TECHNICAL FIELD

The present disclosure relates to a display device.

### BACKGROUND

As the information society develops, demand for display devices for displaying images is increasing in various forms. Various display devices, such as liquid crystal display devices and organic light emitting display devices, are being utilized in recent years.

In a display device, some of the light emitted from the light emitting element layer is not emitted to the outside due to total reflection at the interface between the light emitting element layer and the electrode and/or the interface between the substrate and the air layer, so that the light extraction efficiency may be reduced.

### SUMMARY

Implementations of the disclosure may provide a display device including a substrate, a first planarization layer disposed on the substrate, a second planarization layer disposed on the first planarization layer and having a first opening, a first pixel electrode positioned in a first subpixel among a plurality of subpixels, disposed on the first planarization layer in the first opening, and extending along a side surface of the second planarization layer, a bank disposed on the first pixel electrode, having an upper surface and an inclined side surface, overlapping a portion of the first pixel electrode and the first opening, and including a first hole having a smaller size than the first opening, a first light emitting layer disposed on the first pixel electrode, a common electrode disposed on the first light emitting layer and extending onto the bank, and a plurality of nano-structures positioned in a first subpixel area of the first subpixel or a surrounding area of the first subpixel and disposed on the common electrode.

Implementations of the disclosure may provide a display device including a substrate, a first planarization layer disposed on the substrate, a second planarization layer disposed on the first planarization layer and having a first opening, a first pixel electrode positioned in a first subpixel among a plurality of subpixels, disposed on the first planarization layer in the first opening, and extending along a side surface of the second planarization layer, a bank disposed on the first pixel electrode, having an upper surface and an inclined side surface, overlapping a portion of the first pixel electrode and the first opening, and including a first hole having a smaller size than the first opening, a first light emitting layer disposed on the first pixel electrode, a common electrode disposed on the first light emitting layer and extending onto the bank, and a plurality of first nano-structures positioned in a first subpixel area of the first subpixel or a surrounding area of the first subpixel and positioned on an upper surface of the bank, wherein an emission area of the first subpixel includes: a main emission area corresponding to the first hole, a first sub emission area corresponding to the inclined side surface of the bank, and a second sub emission area corresponding to the plurality of first nano-structures.

### BRIEF DESCRIPTION OF DRAWINGS

The disclosure will be more fully understood from the following detailed description and the accompanying drawings, which are provided for illustration only and are not intended to limit the disclosure.

FIG. 1 is a view illustrating a system configuration of a display device according to implementations of the disclosure;

FIG. 2 illustrates a display panel according to an implementation of the disclosure;

FIG. 3 is a view illustrating a light extraction path in a light emitting element of a display device;

FIGS. 4 and 5 are plan views illustrating a display device according to implementations of the disclosure;

FIGS. 6 and 7 are cross-sectional view taken alone line X-X′ of FIGS. 4 and 5 according to implementations of the disclosure;

FIGS. 8 and 9 are cross-sectional view taken alone line Y-Y′ of FIGS. 4 and 5 according to implementations of the disclosure;

FIG. 10 is a view illustrating a principle of a light extraction structure by a plurality of nano-structures according to implementations of the disclosure;

FIGS. 11 to 13 are example views illustrating a plurality of nano-structures according to implementations of the disclosure;

FIGS. 14 to 16 are graphs illustrating light extraction efficiency according to variables of a plurality of nano-structures according to implementations of the disclosure;

FIG. 17 is a graph illustrating viewing angle efficiency according to implementations of the disclosure;

FIGS. 18 to 20 are simulation photos before and after a plurality of nano-structures are formed according to implementations of the disclosure;

FIG. 21 is a plan view illustrating an emission area of a display panel before and after a plurality of nano-structures are formed according to implementations of the disclosure; and

FIG. 22 is a cross-sectional view illustrating an emission area of a display panel before and after a plurality of nano-structures are formed according to implementations of the disclosure.

### DETAILED DESCRIPTION

Implementations of the disclosure may provide a display device capable of extracting light that is otherwise may not be emitted to the outside.

Implementations of the disclosure may provide a display device capable of enhancing light extraction efficiency by including a plurality of nano-structures.

Objects of implementations of the disclosure are not limited to those set forth herein, and other unmentioned objects would be apparent to one of ordinary skill in the art from the following description.

According to implementations of the disclosure, there may be provided a display device capable of extracting light that otherwise may not be emitted to the outside.

According to implementations of the disclosure, there may be provided a display device capable of enhancing light extraction efficiency by including a plurality of nano-structures.

According to implementations of the disclosure, there may be provided a display device capable of low-power driving by enhancing light extraction efficiency through the inclusion of a plurality of nano-structures.

The effects of the disclosure are not limited to the foregoing objects, and other effects will be apparent to one of ordinary skill in the art from the following detailed description.

In the following description of examples or implementations of the disclosure, reference will be made to the accompanying drawings in which it is shown by way of illustration specific examples or implementations that can be implemented, and in which the same reference numerals and signs can be used to designate the same or like components even when they are shown in different accompanying drawings from one another. Further, in the following description of examples or implementations of the disclosure, detailed descriptions of well-known functions and components incorporated herein will be omitted when it is determined that the description may make the subject matter in some implementations of the disclosure rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” may be used herein to describe elements of the disclosure. Each of these terms is not used to define essence, order, sequence, or number of elements etc., but is used merely to distinguish the corresponding element from other elements.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

Hereinafter, various implementations of the disclosure are described in detail with reference to the accompanying drawings.

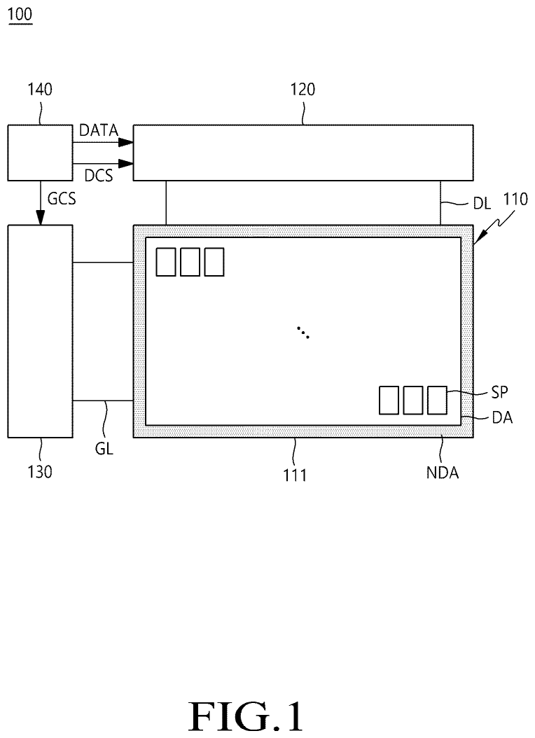

FIG. 1 is a view illustrating a system configuration of a display device according to implementations of the disclosure.

Referring to FIG. 1, a display device 100 according to implementations of the disclosure may include a display panel 110 and display driving circuits, as components for displaying images. The display driving circuit may be a circuit for driving the display panel 110. The display driving circuits may include a data driving circuit 120, a gate driving circuit 130, and a controller 140, but implementations of the disclosure are not limited thereto.

The display panel 110 may include a substrate 111 and a plurality of subpixels SP disposed on the substrate 111.

The substrate 111 may include a display area DA and a non-display area NDA.

The display area DA is an area where images may be displayed, and may also be referred to as an active area. A plurality of subpixels SP for image display may be disposed in the display area DA. The non-display area NDA is an area where no image is displayed and may be an area outside the display area DA. The non-display area NDA may also be referred to as a bezel (or bezel area). The non-display area NDA may include a pad area.

For example, the non-display area NDA may include a first non-display area, a second non-display area, a third non-display area, and a fourth non-display area. The first non-display area may be positioned outside the display area DA in the row direction. The second non-display area may be positioned outside the display area DA in the row direction and may be positioned opposite to the first non-display area. The third non-display area may be positioned outside the display area DA in the column direction. The fourth non-display area may be positioned outside the display area DA in the column direction and may be positioned opposite to the third non-display area.

Among the first to fourth non-display areas, the fourth non-display area may include a pad area where a driving circuit is connected, bonded (or attached), and the first to third non-display areas may have a very small size, but the implementations of the disclosure are not limited thereto.

As another example, the boundary area between the display area DA and the non-display area NDA may be bent so that the non-display area NDA may be positioned under the display area.

No or little change may be made to the non-display area NDA shown to the user when the user views the display device 100 from the front, but implementations of the disclosure are not limited thereto.

The display device 100 according to implementations of the disclosure may be a self-luminous display device in which the display panel 110 emits light by itself, but implementations of the disclosure are not limited thereto. When the display device 100 according to the implementations of the disclosure is a self-emission display device, each of the plurality of subpixels SP may include a light emitting element.

For example, the display device 100 according to implementations of the disclosure may be an organic light emitting diode display in which the light emitting element is implemented as an organic light emitting diode (OLED). As another example, the display device 100 according to implementations of the disclosure may be an inorganic light emitting display device in which the light emitting element is implemented as an inorganic material-based light emitting diode. As another example, the display device 100 according to implementations of the disclosure may be a quantum dot display device in which the light emitting element is implemented as a quantum dot which is self-emission semiconductor crystal. As another example, the display device 100 according to implementations of the disclosure may be a micro LED display device or a mini LED display device.

The structure of each of the plurality of subpixels SP may vary according to the type of the display device 100. For example, when the display device 100 is a self-emission display device in which the subpixels SP emit light by themselves, each subpixel SP may include a light emitting element that emits light by itself, one or more transistors, and one or more capacitors, but implementations of the disclosure are not limited thereto.

Various types of signal lines for driving a plurality of subpixels SP may be disposed on the substrate 111 of the display panel 110. For example, various types of signal lines may include a plurality of data lines DL transferring data signals (also referred to as data voltages or image signals) to a plurality of subpixels SP and a plurality of gate lines GL transferring gate signals (also referred to as scan signals) to the plurality of subpixels SP.

The plurality of data lines DL and the plurality of gate lines GL may cross each other. Each of the plurality of gate lines GL may be disposed to extend in a first direction (e.g., a row direction or column direction). Each of the plurality of data lines DL may be disposed to extend in a second direction (e.g., a column direction or row direction) different from the first direction.

According to implementations of the disclosure, e.g., the first direction may be the row direction, and the second direction may be the column direction. As another example, the first direction may be the column direction, and the second direction may be the row direction. The row direction and the column direction may be relative directions. For example, the column direction may be the row direction depending on the viewpoint, and the row direction may be the column direction depending on the viewpoint. For convenience of description, described below is an example in which each of the plurality of data lines DL is disposed in the column direction, and each of the plurality of gate lines GL is disposed in the row direction, but implementations of the disclosure are not limited thereto. In implementations of the disclosure, the angle between the first direction and the second direction may be 90 degrees or may an angle different from 90 degrees.

The data driving circuit 120 may be a circuit for driving the plurality of data lines DL, and may out data signals to the plurality of data lines DL.

The data driving circuit 120 may receive digital image data DATA from the controller 140 and may convert the received image data DATA into analog data signals (or also referred to as data voltages) and output them to the plurality of data lines DL.

For example, the data driving circuit 120 may be connected with the display panel 110 by a tape automated bonding (TAB) method or connected to a bonding pad of the display panel 110 by a chip on glass (COG) or chip on panel (COP) method or may be implemented by a chip on film (COF) method and connected with the display panel 110, but implementations of the disclosure are not limited thereto.

The data driving circuit 120 may be connected to one side (e.g., an upper or lower side) of the display panel 110. As another example, depending on the driving scheme or the panel design scheme, data driving circuits 120 may be connected with both the sides (e.g., both the upper and lower sides) of the display panel 110, or two or more of the four sides of the display panel 110.

The data driving circuit 120 may be connected outside the display area DA of the display panel 110, but as another example, the data driving circuit 120 may be disposed in the display area DA of the display panel 110.

The gate driving circuit 130 is a circuit for driving the plurality of gate lines GL, and may output gate signals to the plurality of gate lines GL.

The gate driving circuit 130 may receive a first gate voltage corresponding to a turn-on voltage (or also referred to as a turn-on level voltage) and a second gate voltage corresponding to a turn-off voltage (or also referred to as a turn-off level voltage) together with various gate driving control signals GCS, generate gate signals including a section having the first gate voltage and a section having the second gate voltage for a predetermined time (e.g., one frame time), and supply the generated gate signals to the plurality of gate lines GL. For example, the turn-on level voltage may be a high level voltage, and the turn-off level voltage may be a low level voltage. As another example, the turn-on level voltage may be a low level voltage, and the turn-off level voltage may be a high level voltage.

In the display device 100 according to implementations of the disclosure, the gate driving circuit 130 may be embedded, in a gate in panel (GIP) type, in the display panel 110, but implementations of the disclosure are not limited thereto. When the gate driving circuit 130 is of the gate in panel type, the gate driving circuit 130 may be formed on the substrate 111 of the display panel 110 during the manufacturing process of the display panel 110. When the gate driving circuit 130 is of a gate-in-panel type, the gate driving circuit 130 may be referred to as a gate-in-panel circuit (GIPC).

For example, the gate driving circuit 130 may be disposed in the non-active area NDA of the display panel 110. As another example, the gate driving circuit 130 may be disposed in the display area DA of the display panel 110. For example, the gate driving circuit 130 may be disposed in a first partial area in the display area DA (e.g., a left area or a right area in the display area DA). As another example, the gate driving circuit 130 may be disposed in a first partial area in the display area DA (e.g., a left area or right area in the display area DA) and a second partial area (e.g., a right area or left area in the display area DA). As another example, the gate driving circuit 130 may be disposed over the entire display area DA.

When the gate driving circuit 130 is disposed in the display area DA of the display panel 110, the gate driving circuit 130 may vertically overlap the subpixels SP disposed in the display area DA. For example, the gate driving circuit 130 may vertically overlap the light emitting elements and transistors included in the disposed subpixels SP in the display area DA. The gate driving circuit 130 may vertically overlap a plurality of light emitting elements and a plurality of transistors included in a plurality of subpixels SP disposed in the display area DA. The gate driving circuit 130 may include a plurality of transistors. Each of the plurality of transistors included in the gate driving circuit 130 may include an active layer including a first semiconductor material, and each of the plurality of transistors included in the subpixels SP may include an active layer including a second semiconductor material. For example, the first semiconductor material and the second semiconductor material may be substantially identical. As another example, the first semiconductor material and the second semiconductor material may be different from each other. For example, the first semiconductor material may be a silicon-based semiconductor material (e.g., low temperature poly silicon), and the second semiconductor material may be an oxide semiconductor material. For example, the active layer may be, but is not limited to, a semiconductor layer.

The controller 140 is a device for controlling the data driving circuit 120 and the gate driving circuit 130 and may control driving timings for the plurality of data lines DL and driving timings for the plurality of gate lines GL.

The controller 140 may supply a data driving control signal DCS to the data driving circuit 120 to control the data driving circuit 120 and may supply a gate driving control signal GCS to the gate driving circuit 130 to control the gate driving circuit 130.

The controller 140 may be implemented as a separate component from the data driving circuit 120, or the controller 140 and the data driving circuit 120 may be integrated into an integrated circuit (IC).

The controller 140 may be a timing controller used in display technology, a control device that may perform other control functions as well as the functions of the timing controller, or a control device other than the timing controller, or may be a circuit in the control device. The controller 140 may be implemented as various circuits or electronic components, such as an integrated circuit (IC), a field programmable gate array (FPGA), an application specific integrated circuit (ASIC), or a processor, but is not limited thereto.

The controller 140 may be mounted on a printed circuit board or a flexible printed circuit and may be electrically connected with the data driving circuit 120 and the gate driving circuit 130 through the printed circuit board or the flexible printed circuit.

The controller 140 may transmit/receive signals to/from the data driving circuit 120 according to one or more predetermined interfaces. The interface may include, e.g., a low voltage differential signaling (LVDS) interface, an embedded clock point-point interface (EPI), and a serial peripheral interface (SPI), but implementations of the disclosure are not limited thereto.

The display device 100 according to implementations of the disclosure may provide not only an image display function, but also a touch sensing function of detecting whether a touch is made by a touch object, such as a finger or a pen, or detecting the position of a touch.

The display device 100 according to implementations of the disclosure may be a mobile terminal, such as a smart phone or a tablet, displays for vehicles or VR, or a monitor or television (TV) of various sizes but, without limited thereto, may be a display in various types and various sizes capable of displaying information or images.

The display device 100 according to implementations of the disclosure may further include an electronic device such as a camera (image sensor), a detection sensor, or the like. For example, the detection sensor may be a sensor that detects an object or a human body by receiving light such as infrared rays, ultrasonic waves, or ultraviolet rays, but implementations of the disclosure are not limited thereto.

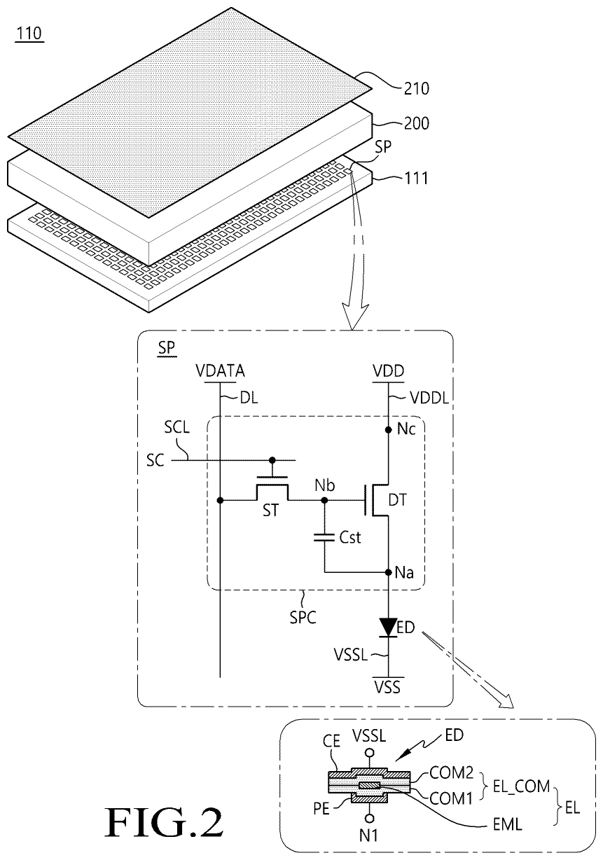

FIG. 2 illustrates a display panel 110 according to an implementation of the disclosure.

Referring to FIG. 2, the display panel 110 according to implementations of the disclosure may include a substrate 111 disposed in a plurality of subpixels SP, an encapsulation layer 200 on the substrate 111, and a color filter layer 210 on the encapsulation layer 200. The encapsulation layer 200 may also be referred to as an encapsulation substrate or an encapsulation unit.

When the display device 100 according to implementations of the disclosure is a self-luminous display device, each of the plurality of subpixels SP disposed on the substrate 111 may include a light emitting element ED and a subpixel circuit SPC for driving the light emitting element ED.

The subpixel circuit SPC may include a plurality of transistors and at least one capacitor for driving the light emitting element ED, but implementations of the disclosure are not limited thereto. In the disclosure, the subpixel circuit SPC may drive the light emitting element ED by supplying a driving current to the light emitting element ED at a predetermined timing. The light emitting element ED may be driven by a driving current to emit light.

The plurality of transistors may include a driving transistor DT for driving the light emitting element ED and a scan transistor ST that is turned on or off according to the scan signal SC.

The driving transistor DT may supply a driving current to the light emitting element ED. The scan transistor ST may be configured to control the electrical state of a corresponding node in the subpixel circuit SPC or to control the state or operation of the driving transistor DT. The at least one capacitor may include a storage capacitor Cst for maintaining a constant voltage during a frame.

To drive the subpixel SP, a data signal VDATA as an image signal and a scan signal SC which is a kind of gate signal may be applied to the subpixel SP. Further, for driving the subpixel SP, a common driving signal including the driving voltage VDD and the base voltage VSS may be applied to the subpixel SP.

The light emitting element ED may include a pixel electrode PE, an intermediate layer EL, and a common electrode CE. The intermediate layer EL may be disposed between the pixel electrode PE and the common electrode CE.

For example, the pixel electrode PE may be an electrode disposed in each subpixel SP, and the common electrode CE may be an electrode commonly disposed in all the subpixels SP. For example, the pixel electrode PE may be an anode, and the common electrode CE may be a cathode. As another example, the pixel electrode PE may be a cathode, and the common electrode CE may be an anode. For convenience of description, an example is described in which the pixel electrode PE is an anode, and the common electrode CE is a cathode.

When the light emitting element ED is an organic light emitting element, the intermediate layer EL may include a light emitting layer EML, a first common intermediate layer COM1 between the pixel electrode PE and the light emitting layer EML, and a second common intermediate layer COM2 between the light emitting layer EML and the common electrode CE. The first common intermediate layer COM1 and the second common intermediate layer COM2 may be collectively referred to as a common intermediate layer EL_COM.

The light emitting layer EML may be disposed for each subpixel SP or may be disposed commonly over a plurality of subpixels SP. The common intermediate layer EL_COM may be commonly disposed across the plurality of subpixels SP, but implementations of the disclosure are not limited thereto.

In other words, the light emitting layer EML may be disposed for each emission area or disposed commonly across a plurality of emission areas. The common intermediate layer EL_COM may be commonly disposed across a plurality of emission areas and non-emission areas, but implementations of the disclosure are not limited thereto.

For example, the first common intermediate layer COM1 may include a hole injection layer HIL, an electron blocking layer EBL, and a hole transport layer HTL, but implementations of the disclosure are not limited thereto. The second common intermediate layer COM2 may include an electron transport layer ETL, a hole blocking layer HBL, and an electron injection layer EIL, but implementations of the disclosure are not limited thereto.

The hole injection layer HIL may inject holes from the pixel electrode PE to the hole transport layer HTL, and the hole transport layer HTL may transport holes to the light emitting layer EML. The electron injection layer EIL may inject electrons from the common electrode CE to the electron transport layer ETL, and the electron transport layer ETL may transport electrons to the light emitting layer EML.

For example, the common electrode CE may be electrically connected to the base voltage line VSSL. The base voltage VSS, which is one type of the common voltage, may be applied to the common electrode CE through the base voltage line VSSL. The pixel electrode PE may be electrically connected directly or indirectly (through another transistor) to the first node Na of the driving transistor DT of each subpixel SP. In the disclosure, “base voltage VSS” may also be referred to as a first common voltage, a low-potential power voltage, or a low-potential voltage, and “base voltage line VSSL” may also be referred to as a first common voltage line, a low-potential power voltage line, or a low-potential voltage line.

Each light emitting element ED may include portions where the pixel electrode PE, the light emitting layer EML in the intermediate layer LE, and the common electrode CE overlap. A predetermined light emitting area may be formed by each light emitting element ED. For example, the light emitting area of each light emitting element ED may include an overlapping area of the pixel electrode PE, the light emitting layer EML in the intermediate layer EL, and the common electrode CE.

For example, the light emitting element ED may be an organic light emitting diode (OLED), an inorganic light emitting diode (LED), a quantum dot light emitting element, a micro LED, or a mini LED, but implementations of the disclosure are not limited thereto. For example, when the light emitting element ED is an organic light emitting diode (OLED), the intermediate layer EL of the light emitting element ED may include an intermediate layer EL including an organic material.

The driving transistor DT may be a driving transistor for supplying a driving current to the light emitting element ED. The driving transistor DT may be connected between a driving voltage line VDDL and the light emitting element ED.

The driving transistor DT may include a first node Na, a second node Nb, and a third node Nc. The first node Na may be electrically connected to the light emitting element ED, the second node Nb may receive a data signal VDATA, and the third node Nc may receive a driving voltage VDD, which is another kind of common voltage, from the driving voltage line VDDL. The driving transistor DT may be connected on the first node Na and the third node Nc. In the disclosure, “driving voltage VDD” may also be referred to as a second common voltage, a high-potential power voltage, or a high-potential voltage, and “driving voltage line VDDL” may also be referred to as a second common voltage line, a low-potential power voltage line, or a low-potential voltage line.

In the driving transistor DT, the second node Nb may be a gate node, the first node Na may be a source node or a drain node, and the third node Nc may be a drain node or a source node. Hereinafter, for convenience of description, an example is described in which in the driving transistor DT, the second node Nb may be a gate node, the first node Na may be a source node, and the third node Nc may be a drain node, but implementations of the disclosure are not limited thereto.

The scan transistor ST included in the subpixel circuit SPC illustrated in FIG. 2 may be a switching transistor for transferring the data signal VDATA, which is an image signal, to the second node Nb, which is the gate node of the driving transistor DT.

The scan transistor ST may be controlled to be turned on and off by the scan signal SC, which is a kind of gate signal applied through the scan line SCL, which is a type of the gate line GL, to control electrical connection between the second node Nb of the driving transistor DT and the data line DL. The drain electrode or the source electrode of the scan transistor ST may be electrically connected to the data line DL, the source electrode or the drain electrode of the scan transistor ST may be electrically connected to the second node Nb of the driving transistor DT, and the gate electrode of the scan transistor ST may be electrically connected to the scan line SCL.

The storage capacitor Cst may be electrically connected between the first node Na and second node Nb of the driving transistor DT. The storage capacitor Cst may include at least one capacitor electrode electrically connected to the first node Na of the driving transistor DT or corresponding to the first node Na of the driving transistor DT, and at least one capacitor electrode electrically connected to the second node Nb of the driving transistor DT or corresponding to the second node Nb of the driving transistor DT.

The capacitor Cst may be an external capacitor intentionally designed to be outside the driving transistor DT, but not a parasite capacitor (e.g., Cgs or Cgd) which is an internal capacitor that may be present between the first node Na and the second node Nb of the driving transistor DT, but implementations of the disclosure are not limited thereto.

Each of the driving transistor DT and the scan transistor ST may be an n-type transistor or a p-type transistor, but implementations of the disclosure are not limited thereto. For example, one of the driving transistor DT and the scan transistor ST may be either an n-type transistor or a p-type transistor.

The display panel 110 may have a top emission structure or a bottom emission structure. When the display panel 110 has a top emission structure, at least a portion of the subpixel circuit SPC may overlap at least a portion of the light emitting element ED in a vertical direction. Accordingly, the area of the emission area may increase and the aperture ratio may increase. When the display panel 110 has a bottom emission structure, the subpixel circuit SPC may not overlap the light emitting element ED in the vertical direction.

As illustrated in FIG. 2, the subpixel circuit SPC may have a 2T (Transistor) 1C (Capacitor) structure including two transistors DT and ST and one capacitor Cst. In some cases, the subpixel circuit SPC may further include one or more transistors or may further include one or more capacitors, but implementations of the disclosure are not limited thereto.

For example, the subpixel circuit SPC may have a 3T1C structure including 3 transistors and 1 capacitor. For example, the subpixel circuit SPC may have an 8T1C structure including 8 transistors and 1 capacitor. As another example, the subpixel circuit SPC may have a 6T2C structure including 6 transistors and 2 capacitors. As another example, the subpixel circuit SPC may have a 7T1C structure including 7 transistors and 1 capacitor, but implementations of the disclosure are not limited thereto.

Depending on the structure of the subpixel circuit SPC, the type and number of gate lines or the gate signals supplied to the subpixel SP may vary. Further, the type and the number of common driving signals supplied to the subpixel SP may vary depending on the structure of the subpixel circuit SPC.

Since the circuit elements (e.g., the light emitting element ED implemented as an organic light emitting diode (OLED) including an organic material) in each subpixel SP are vulnerable to external moisture or oxygen, the encapsulation layer 200 may be disposed on the display panel 110. The encapsulation layer 200 may prevent external moisture or oxygen from penetrating into circuit elements (e.g., the light emitting element ED). The encapsulation layer 200 may be configured in various forms so that the light emitting elements ED do not contact moisture or oxygen. For example, the encapsulation layer 200 may be constituted of two or more layers in which organic films and inorganic films are alternately stacked, but implementations of the disclosure are not limited thereto.

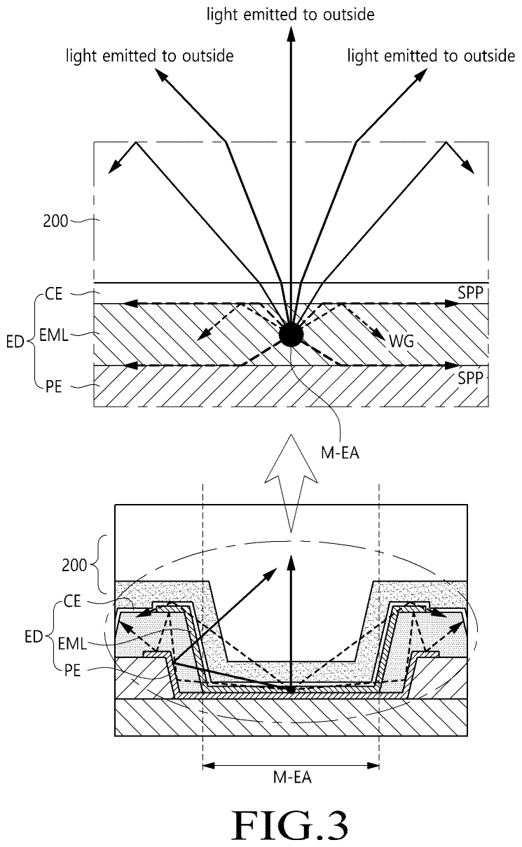

FIG. 3 is a view illustrating a light extraction path in a light emitting element of a display device.

Referring to FIG. 3, the display device may include a main emission area M-EA. The main emission area M-EA may include a light emitting element ED and an encapsulation layer 200 disposed on the light emitting element ED. The light emitting element ED may include a pixel electrode PE, a light emitting layer EML, and a common electrode CE, but the disclosure is not limited thereto.

Referring to FIG. 3, in the display device 100 the light emitted to the outside from the light emitting element ED of the main emission area M-EA may include the light that is incident at an angle of 90 degrees or less from under the light emitting element ED and emitted in a straight line or the light that is reflected from the inclined surface of the pixel electrode PE and emitted to the outside, but the disclosure is not limited thereto. Such light emitted to the outside may have an external quantum efficiency (EQE) of 30% or less, and thus may be emitted with low light extraction efficiency.

In the display device 100, some of the light emitted from the light emitting element ED of the main emission area M-EA includes the light absorbed (or annihilated) by the waveguide WG (or optical waveguide) at the interface between the substrate and the air layer (i.e., light trapped inside the light emitting element) and/or the light SPP that may not be emitted to the outside due to, e.g., total reflection at the interface between the pixel electrode PE and the common electrode CE, so that the light extraction efficiency EQE may be reduced.

Thus, the display device 100 according to implementations of the disclosure may be modified to include nano-structures for extracting the light that would otherwise be absorbed (annihilated) by the waveguide WG (or optical waveguide) among the light emitted from the light emitting element ED and/or the light SPP that may otherwise not be emitted to the outside due to, e.g., total reflection at the interface between the pixel electrode PE and the common electrode CE, thereby increasing light extraction efficiency and enhancing external quantum efficiency (EQE).

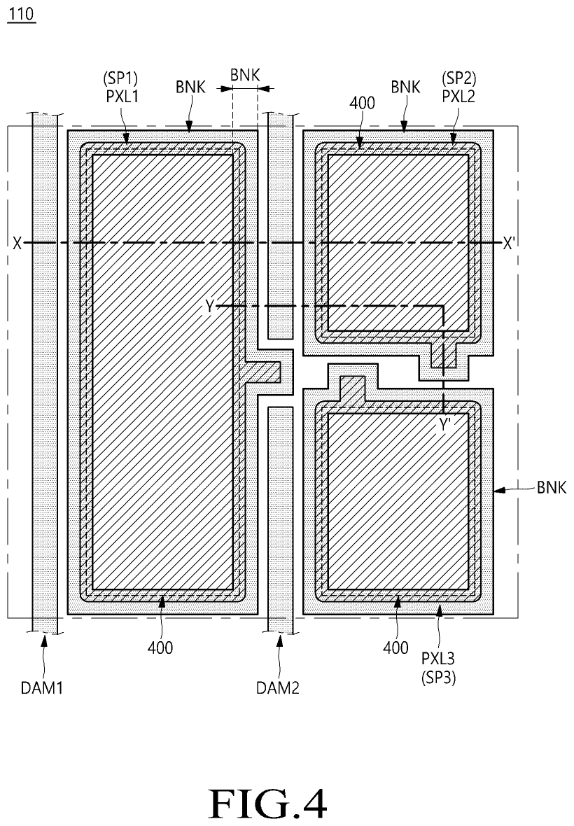

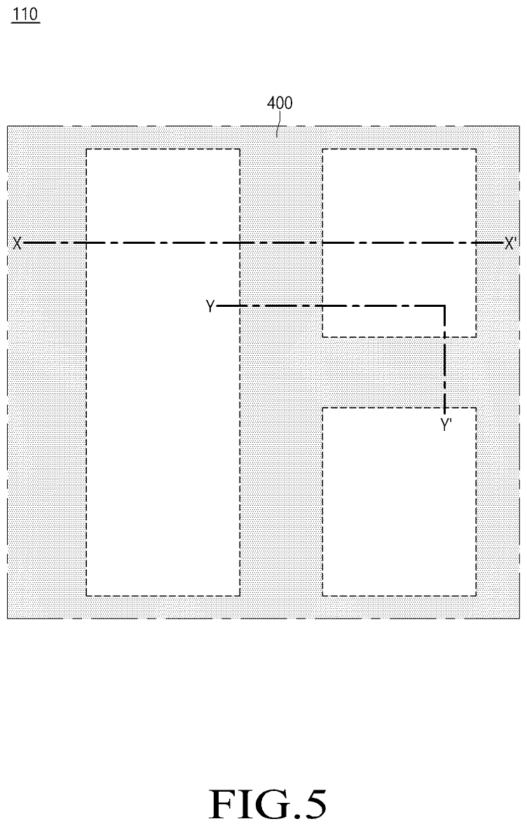

FIGS. 4 and 5 are plan views illustrating a display panel 100 according to implementations of the disclosure.

Referring to FIG. 4, the display panel 110 according to implementations of the disclosure may include a plurality of subpixels, a plurality of dams, a bank BNK, and a second planarization layer 400.

For example, the plurality of subpixels may include a light emitting element and a subpixel circuit for driving the light emitting element. The plurality of subpixels may include a first subpixel SP1, a second subpixel SP2, and a third subpixel SP3, but the disclosure is not limited thereto.

For example, the plurality of dams may include a first dam DAM1 and a second dam DAM2, but the disclosure is not limited thereto. As another example, the plurality of dams may be positioned inside the hole of the surrounding bank BNK, the first dam DAM1 may be positioned around the first subpixel SP1, and the second dam DAM2 may be positioned at the boundary between the first subpixel SP1 and the second subpixel SP2 and/or the boundary between the first subpixel SP1 and the third subpixel SP3, but the disclosure is not limited thereto.

For example, the first dam DAM1 and the second dam DAM2 may be formed to prevent light emitted from one of the subpixels from being mixed with light from the light emitting elements included in the other subpixels, but the disclosure is not limited thereto.

For example, the bank BNK may be positioned to overlap the plurality of subpixels. The bank BNK may block light from the outside or block light reflected from the outside, but the disclosure is not limited thereto.

The bank BNK may include an organic layer including an organic insulating material. For example, the bank BNK may be formed of a material including a black pigment or the like, or an organic material such as benzocyclobutene resin, polyimide resin, acrylic resin, or photosensitive polymer, but the disclosure is not limited thereto. When the bank BNK is formed of a material including a black pigment or a black dye, it may be a black bank, but the disclosure is not limited thereto.

For example, the plurality of dams may include the material of the bank BNK, but the disclosure is not limited thereto. For example, the first dam DAM1 and the second dam DAM2 may include the same material as the bank BNK, but the disclosure is not limited thereto.

Referring to FIGS. 4 and 5, the display panel 110 according to implementations of the disclosure may include a second planarization layer 400.

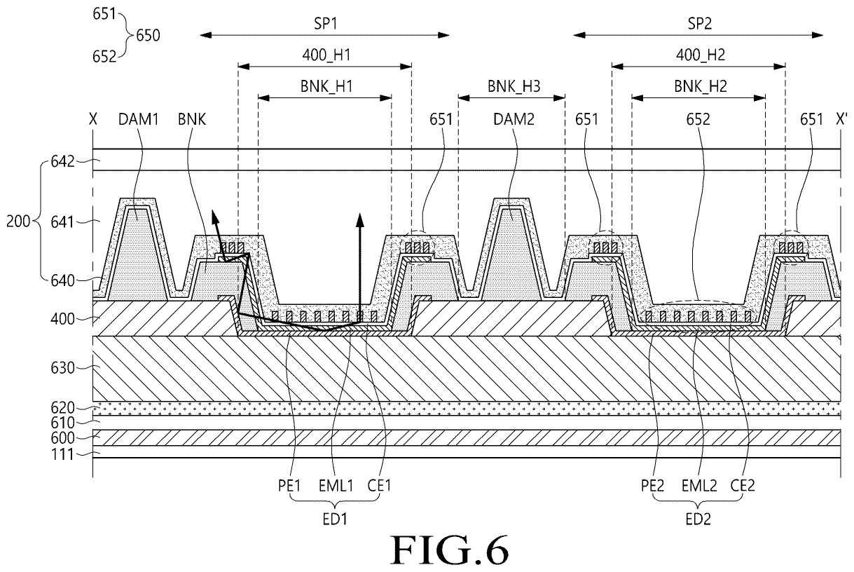

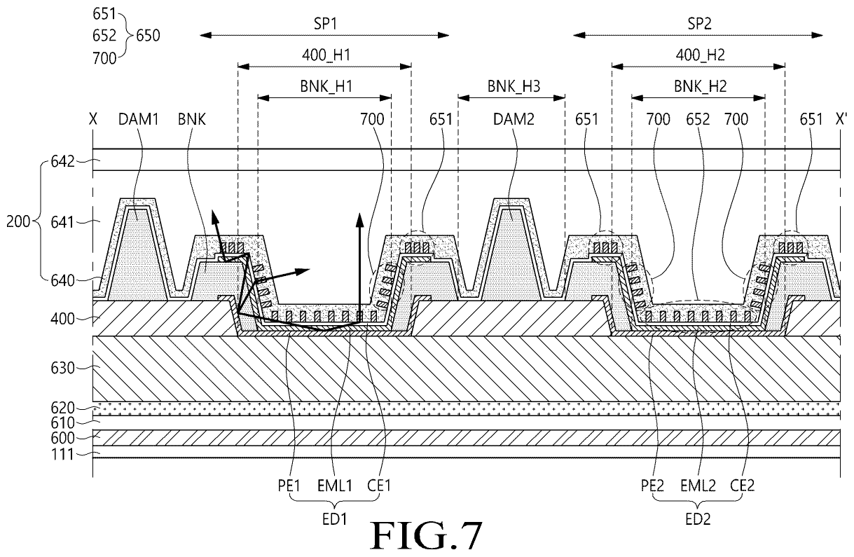

For example, the second planarization layer 400 may be positioned to overlap the plurality of subpixels, but the disclosure is not limited thereto. The second planarization layer 400 may be formed on the entire substrate of the display panel including a plurality of openings, but the disclosure is not limited thereto. This is described in more detail in connection with the cross-sectional structure of FIGS. 6 and 7 below.

Hereinafter, a cross-sectional structure of a display device according to implementations of the disclosure is described in more detail. Descriptions substantially the same as those described in FIGS. 1 to 5 may be omitted.

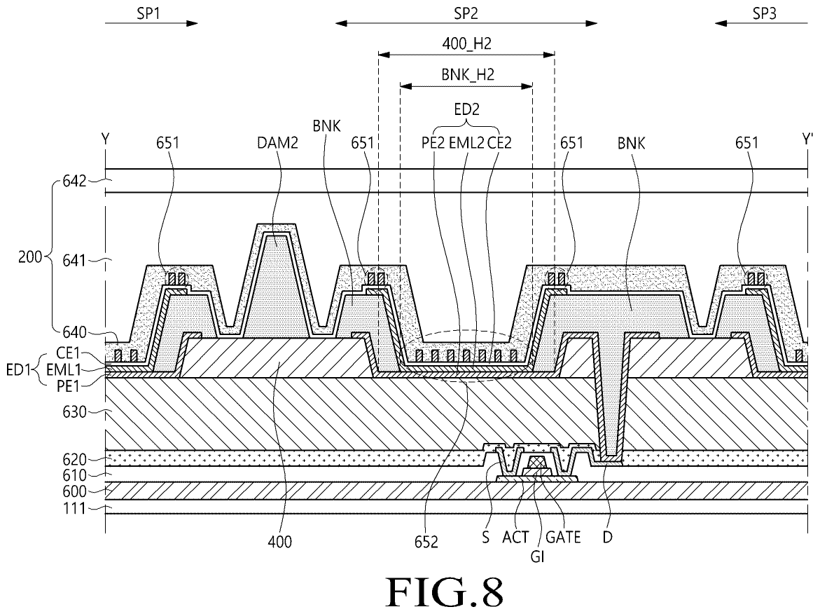

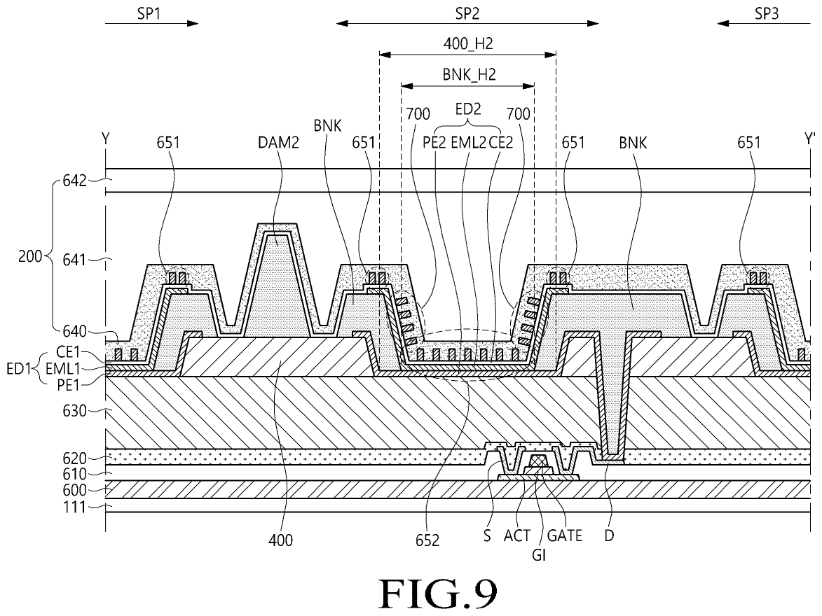

FIGS. 6 and 7 are cross-sectional view taken alone line X-X′ of FIGS. 4 and 5 according to implementations of the disclosure. FIGS. 8 and 9 are cross-sectional view taken alone line Y-Y′ of FIGS. 4 and 5 according to implementations of the disclosure.

Referring to FIGS. 6 and 7, a display panel 110 according to implementations of the disclosure may include a substrate 111, insulation layers, a plurality of subpixels including a plurality of light emitting elements, a bank BNK, a plurality of dams, an encapsulation layer 200, and a plurality of nano-structures 650, but implementations of the disclosure are not limited thereto.

The substrate 111 may be formed of a single layer or a plurality of layers. For example, the substrate 111 may be a polyimide (PI) layer, but the disclosure is not limited thereto.

Insulation layers may be included on the substrate 111. For example, the insulation layers may include a buffer layer 600, a gate insulation layer 610 disposed on the buffer layer 600, and an inorganic insulation layer 620 disposed on the gate insulation layer 610, but the disclosure is not limited thereto.

A first planarization layer 630 may be disposed on the insulation layers. For example, the first planarization layer 630 may be an organic insulation layer including an organic insulating material, but the disclosure is not limited thereto.

The display panel 110 according to implementations of the disclosure may include a second planarization layer 400. For example, the second planarization layer 400 may be disposed on the first planarization layer 630 and may include a plurality of openings, but the disclosure is not limited thereto.

For example, the plurality of openings of the second planarization layer 400 may include a first opening 400_H1 positioned in the first subpixel SP1 and a second opening 400_H2 positioned in the second subpixel SP2, but the disclosure is not limited thereto.

The plurality of subpixels may include a plurality of light emitting elements. The plurality of subpixels may include a first subpixel SP1 and a second subpixel SP2, but the disclosure is not limited thereto.

For example, the first subpixel SP1 may include a first light emitting element ED1. The first light emitting element ED1 may include a first pixel electrode PE1, a first light emitting layer EML1, and a common electrode CE1, but the disclosure is not limited thereto.

For example, the first pixel electrode PE1 may be positioned in the first subpixel SP1, and may be disposed on the first planarization layer 630 in the first opening 400_H1. As another example, the first pixel electrode PE1 may extend along a side surface of the second planarization layer 400, but the disclosure is not limited thereto. As another example, the first pixel electrode PE1 may include an inclined surface extending along a side surface of the second planarization layer 400, but the disclosure is not limited thereto.

For example, the first light emitting layer EML1 may be disposed on the first pixel electrode PE1, and the common electrode CE1 may be disposed on the first light emitting layer EML1, but the disclosure is not limited thereto.

For example, the second subpixel SP2 may include a second light emitting element ED2. The second light emitting element ED2 may include a second pixel electrode PE2, a second light emitting layer EML2, and a common electrode CE2, but the disclosure is not limited thereto.

For example, the second pixel electrode PE2 may be positioned in the second subpixel SP2, and may be disposed on the second planarization layer 400 in the second opening 400_H2. As another example, the second pixel electrode PE2 may extend along the side surface of the second planarization layer 400, but the disclosure is not limited thereto. As another example, the second pixel electrode PE2 may include an inclined surface extending along a side surface of the second planarization layer 400, but the disclosure is not limited thereto.

For example, the second light emitting layer EML2 may be disposed on the second pixel electrode PE2, and the common electrode CE2 may be disposed on the second light emitting layer EML2, but the disclosure is not limited thereto.

For example, the bank BNK may be positioned to overlap the plurality of subpixels. The bank BNK may block light from the outside or block light reflected from the outside, but the disclosure is not limited thereto.

The bank BNK may be disposed on the first pixel electrode PE1 of the first subpixel SP1. The bank BNK may have an upper surface and an inclined side surface, and may include a first hole BNK_H1.

For example, the first hole BNK_H1 of the bank BNK may overlap a portion of the first pixel electrode PE1 and the first opening 400_H1, and may include a size smaller than that of the first opening 400_H1, but the disclosure is not limited thereto.

The bank BNK may be disposed on the second pixel electrode PE2 of the second subpixel SP2. The bank BNK may have an upper surface and an inclined side surface, and may include a second hole BNK_H.

For example, the second hole BNK_H2 of the bank BNK may overlap a portion of the second pixel electrode PE2 and the second opening 400_H2, and may have a size smaller than that of the second opening 400_H2, but the disclosure is not limited thereto.

For example, the bank BNK may include a third hole BNK_H3 between the first hole BNK_H1 and the second hole BNK_H2.

The bank BNK may include an organic layer including an organic insulating material. For example, the bank BNK may be formed of a material including a black pigment or the like, or an organic material such as benzocyclobutene resin, polyimide resin, acrylic resin, or photosensitive polymer, but the disclosure is not limited thereto. When the bank BNK is formed of a material including a black pigment or a black dye, it may be a black bank, but the disclosure is not limited thereto.

For example, the common electrodes CE1 and CE2 may extend onto the bank BNK, but the disclosure is not limited thereto.

The plurality of dams may include a first dam DAM1 and a second dam DAM2, but the disclosure is not limited thereto. For example, the first dam DAM1 and the second dam DAM2 may be formed to prevent light emitted from one of the subpixels from being mixed with light from the light emitting elements included in the other subpixels, but the disclosure is not limited thereto.

For example, the plurality of dams may be positioned inside the hole of the surrounding bank BNK, the first dam DAM1 may be positioned around the first subpixel SP1, and the second dam DAM2 may be positioned at the boundary between the first subpixel SP1 and the second subpixel SP2, but the disclosure is not limited thereto.

For example, the second dam DAM2 may be positioned at the boundary between the first subpixel SP1 and the second subpixel SP2, may be positioned on the second planarization layer 400, and may be positioned inside the third hole BNK_H3, but the disclosure is not limited thereto.

For example, the heights of the first dam DAM1 and the second dam DAM2 may be larger than or equal to the height of the bank BNK, but the disclosure is not limited thereto.

For example, the first dam DAM1 and the second dam DAM2 may include the same material as the bank BNK, but the disclosure is not limited thereto.

The encapsulation layer 200 may be disposed on the light emitting element and may include a first inorganic layer 640, a first organic layer 641, and a second inorganic layer 642.

For example, the encapsulation layer 200 may prevent moisture or oxygen from penetrating into the light emitting element. For example, the encapsulation layer 200 may prevent moisture or oxygen from penetrating into the organic material included in the intermediate layer of the light emitting element. The encapsulation layer 200 may be composed of a single layer or a plurality of layers, but the disclosure is not limited thereto.

For example, the first inorganic layer 640 may be disposed on the common electrodes CE1 and CE2, and may be formed along a shape where the common electrodes CE1 and CE2 are disposed, but the disclosure is not limited thereto.

For example, the first organic layer 641 may be disposed on the first inorganic layer 640, and may planarize the first inorganic layer 640, but the disclosure is not limited thereto.

For example, the second inorganic layer 642 may be disposed on the first organic layer 641, but the disclosure is not limited thereto.

For example, the first inorganic layer 640 and the second inorganic layer 642 may include an inorganic encapsulation layer including an inorganic insulating material, and the first organic layer 641 may include an organic encapsulation layer including an organic insulating material, but the disclosure is not limited thereto.

The display panel 110 according to implementations of the disclosure may include a plurality of nano-structures 650.

Considering one subpixel area, a plurality of nano-structures 650 can be disposed in the subpixel area or a surrounding area of the subpixel area. For example, the plurality of nano-structures 650 may be disposed on the common electrode CE1 in the first subpixel SP1 area or the surrounding area of the first subpixel. As another example, the plurality of nano-structures 650 may be disposed on the common electrode CE2 in the second subpixel SP2 area or the surrounding area of the second subpixel.

For example, the plurality of nano-structures 650 may include, but are not limited to, a plurality of first nano-structures 651, a plurality of second nano-structures 652, and a plurality of third nano-structures 700.

For example, in the first subpixel SP1 and the second subpixel SP2, the plurality of first nano-structures 651 may be positioned on the upper surface of the bank BNK, but the disclosure is not limited thereto. As another example, the first pixel electrode PE1 or the second pixel electrode PE2 has an inclined surface extending along the side surface of the second planarization layer 400, and at least one of the plurality of first nano-structures 651 may transmit light reflected from the inclined surface to be extracted to the outside, but the disclosure is not limited thereto.

For example, in the first subpixel SP1, the plurality of second nano-structures 652 may be positioned inside the first hole BNK_H1 of the bank BNK, but the disclosure is not limited thereto. As another example, in the second subpixel SP2, the plurality of second nano-structures 652 may be positioned inside the second hole BNK_H2 of the bank BNK, but the disclosure is not limited thereto.

For example, in the first subpixel SP1 and the second subpixel SP2, the plurality of third nano-structures 700 may be positioned on the inclined side of the bank BNK, but the disclosure is not limited thereto. For example, by including a plurality of third nano-structures 700, light reflected by the first pixel electrode PE1 and the second pixel electrode PE2 may be extracted by the plurality of third nano-structures 700, but the disclosure is not limited thereto.

For example, the encapsulation layer 200 may be disposed on the plurality of nano-structures 650, but the disclosure is not limited thereto. For example, the plurality of nano-structures 650 may be disposed on the common electrodes CE1 and CE2, and the first inorganic layer 640 of the encapsulation layer 200 may be formed along a shape where the common electrodes CE1 and CE2 are disposed, but the disclosure is not limited thereto.

For example, the plurality of nano-structures 650 and the encapsulation layer 200 may include different refractive indices, but the disclosure is not limited thereto. As another example, the refractive index of the plurality of nano-structures 650 may be formed to be lower than the refractive index of the encapsulation layer 200, but the disclosure is not limited thereto.

Referring to FIGS. 8 and 9, the display panel 110 according to implementations of the disclosure may include a substrate 111, insulation layers, a transistor unit, a plurality of subpixels including a plurality of light emitting elements, a bank BNK, a plurality of dams, an encapsulation layer 200, and a plurality of nano-structures 650, but implementations of the disclosure are not limited thereto. Descriptions substantially the same as those described in FIGS. 5 to 6 may be omitted.

For example, the transistor unit may be disposed on the insulation layers 600, 610, and 620 on the substrate 111, and may include a thin film transistor, a storage capacitor, and various electrodes or signal lines, but the disclosure is not limited thereto.

For example, the thin film transistor may include an active layer ACT, a gate electrode GATE, a source electrode S, and a drain electrode D, but the disclosure is not limited thereto.

For example, the active layer ACT may be disposed on the buffer layer 600. The active layer ACT may include a channel area where a channel is formed, a source connection area on one side of the channel area, and a drain connection area on the other side of the channel area, but the disclosure is not limited thereto.

For example, the active layer ACT may include a first semiconductor material. The first semiconductor material may include an oxide semiconductor, amorphous silicon, polysilicon, or low-temperature polysilicon (LTPS), but implementations of the disclosure are not limited thereto.

For example, the gate insulation layer 610 may be disposed on the active layer ACT, but the disclosure is not limited thereto. A gate electrode GATE may be disposed on the gate insulation layer 610, but the disclosure is not limited thereto. An insulation layer GI of the same material as the gate insulation layer 610 may be included between the active layer ACT and the gate electrode GATE, but the disclosure is not limited thereto.

For example, a source electrode S may be connected to one side of the active layer ACT and a drain electrode D may be connected to the other side, but the disclosure is not limited thereto. The source electrode S and the drain electrode D may be disposed in the inorganic insulation layer 620, but the disclosure is not limited thereto. The source electrode S and the drain electrode D may be connected to the source connection area and the drain connection area, respectively, of the active layer ACT through the hole of the gate insulation layer 610.

For example, the second light emitting element ED2 of the second subpixel SP2 may be connected to the transistor unit, but the disclosure is not limited thereto. For example, the second pixel electrode PE2 of the second light emitting element ED2 may be connected to the source electrode S or the drain electrode D of the transistor through a contact hole, but the disclosure is not limited thereto.

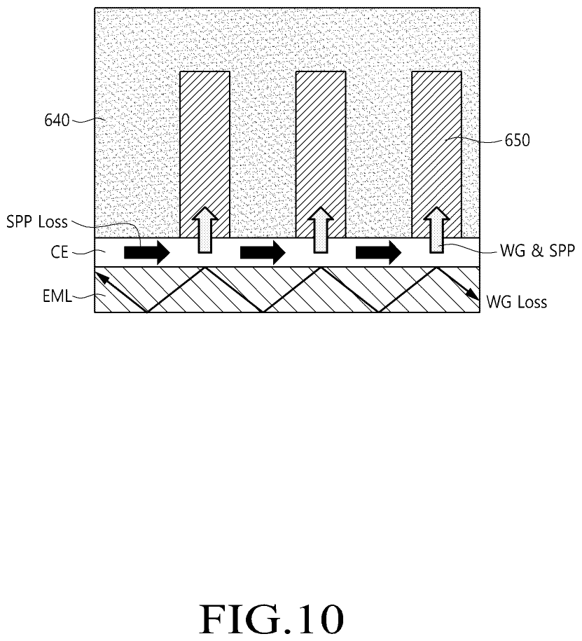

FIG. 10 is a view illustrating a principle of a light extraction structure by a plurality of nano-structures according to implementations of the disclosure.

Referring to FIG. 10, in scenarios where some of the light emitted from the light emitting element of the display panel is absorbed (annihilated) by the waveguide WG (or optical waveguide) at the interface between the light emitting layer EML and the common electrode CE (i.e., light trapped inside the light emitting element), and where some light is light SPP that is not be emitted to the outside due to, e.g., total reflection at the interface of the common electrode CE, the light extraction efficiency to the outside may be reduced. However, implementations of the present disclosure are not limited to these scenarios.

The plurality of nano-structures 650 may extract WG or/and SPP light by causing fluorescence emission in the direction of the first inorganic layer 640, but this disclosure is not limited thereto. For example, the plurality of nano-structures 650 may include an organic material, but the disclosure is not limited thereto. For example, the plurality of nano-structures 650 may include a DAAQ (1,5-diaminoanthraquinone) material, but the disclosure is not limited thereto. As another example, as the light induced through the nano-structure 650 may cause π*→π transition of the DAAQ(1,5-diaminoanthraquinone) material from the amino group in the molecules to a carbonyl group, so that charge transfer proceeds, strong fluorescence emission may occur toward the first inorganic layer 640, thereby enabling extraction of the WG or/and SPP light that has been lost, but the disclosure is not limited thereto.

For example, the plurality of nano-structures 650 may extract WG or/and SPP light to the front using a difference in refractive index, but the disclosure is not limited thereto. For example, the first inorganic layer 640 and the plurality of nano-structures 650 may include different refractive indices, but the disclosure is not limited thereto. As another example, the refractive index of the plurality of nano-structures 650 may be formed to be lower than the refractive index of the first inorganic layer 640, but the disclosure is not limited thereto.

For example, the plurality of nano-structures 650 may be formed in a vertical direction on the common electrode CE of the light emitting element, and WG or/and SPP light induced by fluorescence emission may be extracted into the first inorganic layer 640 through the plurality of nano-structures 650 due to a refractive index difference, but the disclosure is not limited thereto.

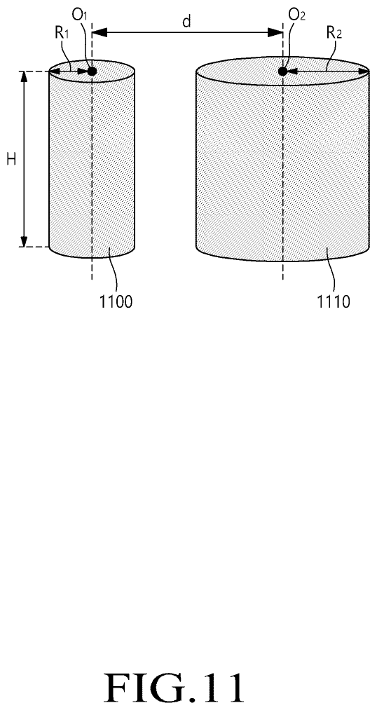

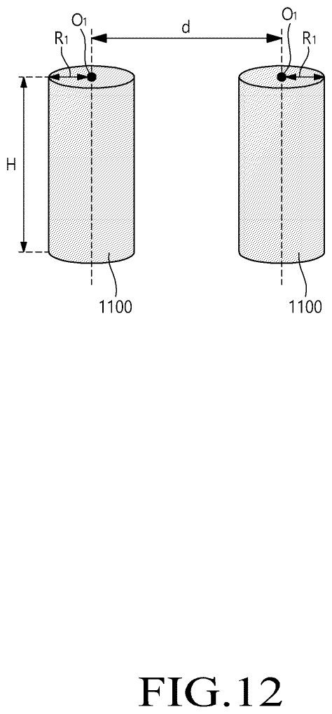

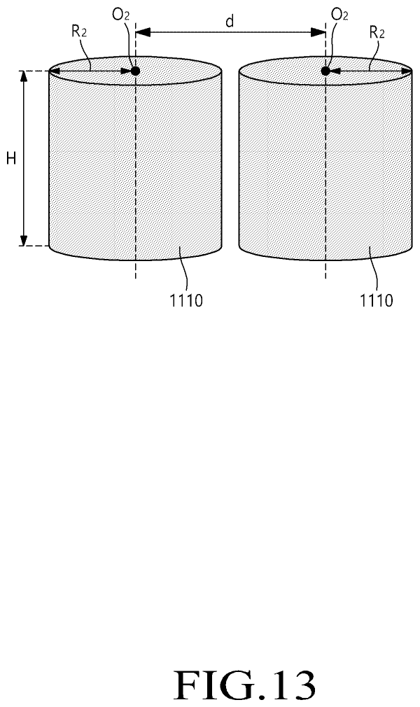

FIGS. 11 to 13 are example views illustrating a plurality of nano-structures according to implementations of the disclosure.

Referring to FIGS. 11 to 13, a variable for controlling the amount of light passing through the plurality of nano-structures may be included, at least one nano-structure 1110 may have a center O₂, a radius R₂, and a height H, and the rear surface of another nano-structure 1100 may be formed as a polygonal column having a center O₁, a radius R₁, and a height H, but the disclosure is not limited thereto.

For example, the distance d between the center O₂ and the center O₂ of at least one nano-structure 1110 may be included, and the distance d between the center O₁ and the center O₁ of other nano-structures 1100 may be included. In other words, the distance d between the centers of the plurality of nano-structures may be included, but the disclosure is not limited thereto.

Referring to FIGS. 11 to 13, the rear surface of at least one nano-structure 1110 of the plurality of nano-structures according to implementations of the disclosure may have a size different from the rear surface of another nano-structure 1100, but the disclosure is not limited thereto.

For example, the rear surface of at least one nano-structure 1110 is larger than the rear surface of another nano-structure 1100, and the amount of light passing through at least one nano-structure 1110 may be larger than the amount of light passing through the other nano-structure 1100, but the disclosure is not limited thereto.

Hereinafter, the light extraction efficiency according to the variable affecting the amount of light passing through the plurality of nano-structures is described.

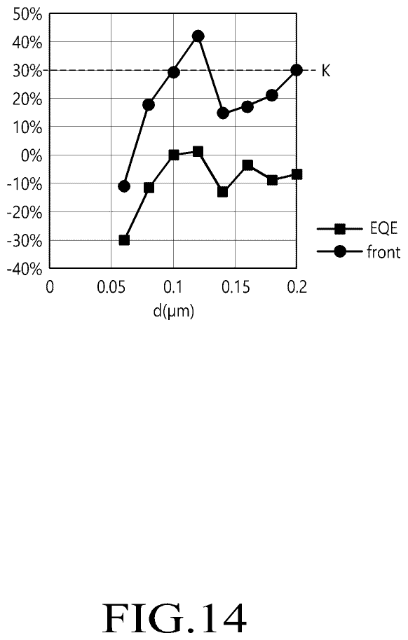

FIGS. 14 to 16 are graphs illustrating light extraction efficiency according to variables of a plurality of nano-structures according to implementations of the disclosure.

FIG. 14 is a graph of light extraction efficiency according to the distance d between the center of at least one nano-structure among a plurality of nano-structures and the center of another nano-structure. It may be identified that the external quantum efficiency (EQE) is not affected by the distance d while the front extraction efficiency is the maximum when the distance d is about 0.12 for K (up to 30%), which is the maximum value of the existing light extraction efficiency.

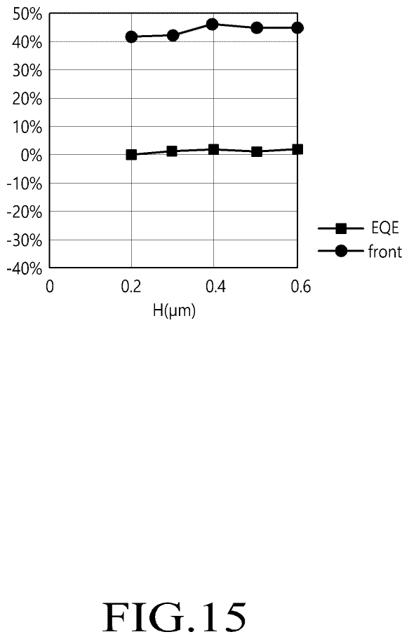

FIG. 15 is a graph illustrating light extraction efficiency according to the height H of a plurality of nano-structures. It is identified that the external quantum efficiency (EQE) is not affected by the height H, nor is the front extraction efficiency affected by the change in height.

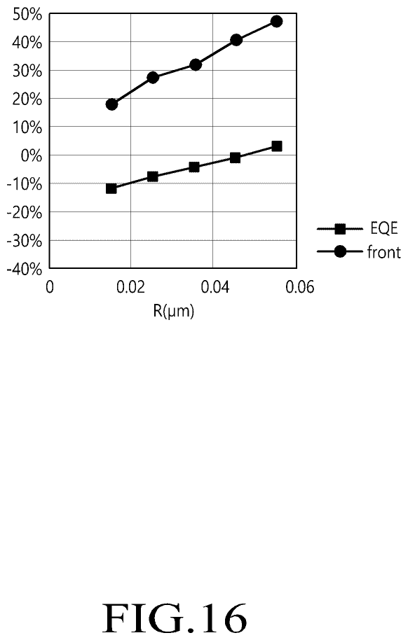

FIG. 16 is a graph illustrating light extraction efficiency according to the radius R of a plurality of nano-structures. It may be identified that both the external quantum efficiency (EQE) and the front extraction efficiency are enhanced as the radius R increases.

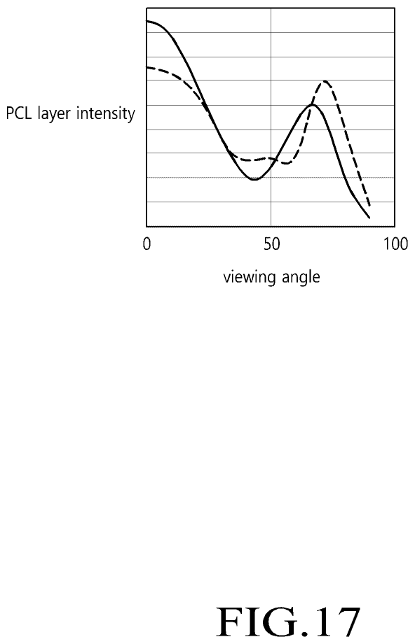

FIG. 17 is a graph illustrating viewing angle efficiency according to implementations of the disclosure.

Referring to FIG. 17, for the strength of the encapsulation layer according to the viewing angle, from the (solid line) graph for a structure including a plurality of nano-structures in the (dashed line) graph for the conventional structure, it may be identified that in the structure including the plurality of nano-structures of total reflection, light collection occurs at an angle of 40 degrees or less. Thus, as the efficiency of viewing angle extraction is enhanced by the plurality of nano-structures extracting the light otherwise lost by total reflection, the light collection effect of the plurality of nano-structures may be identified.

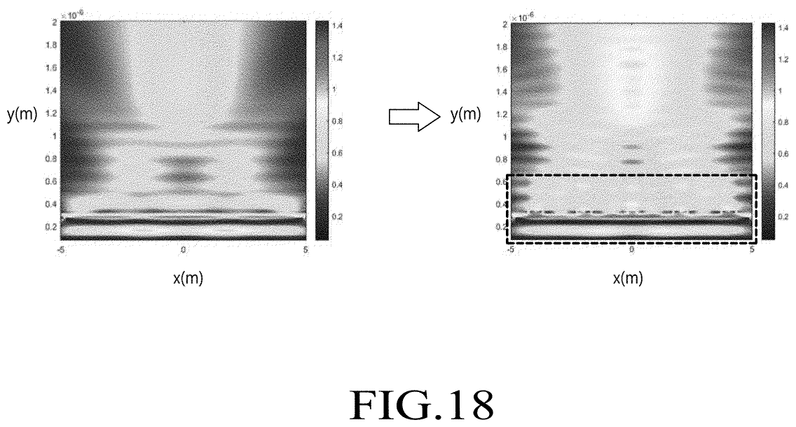

FIGS. 18 to 20 are simulation photos before and after a plurality of nano-structures are formed according to implementations of the disclosure. The simulation proposes an optical device for increasing 3D/immersion effects by implementing two or more virtual image planes while implementing an up-floating virtual image using an optical device. To that end, it was measured using an optical surface that may be driven in two or more polarization modes. Preferably, the photos are ones measured for the simulation before and after forming the plurality of nano-structures using a metasurface that may operate in the transverse magnetic (TM) mode and transverse electric (TE) mode.

FIG. 18 regards the measurement in the transverse electric (TM) mode among the propagation modes. It may be identified that, after a plurality of nano-structures are formed in the dashed-line box, the light (i.e., light trapped inside the light emitting element) that would otherwise be absorbed (or annihilated) by the waveguide WG (or optical waveguide) at the interface between the substrate and the light emitting element is extracted in a wider area and with a larger amount of light.

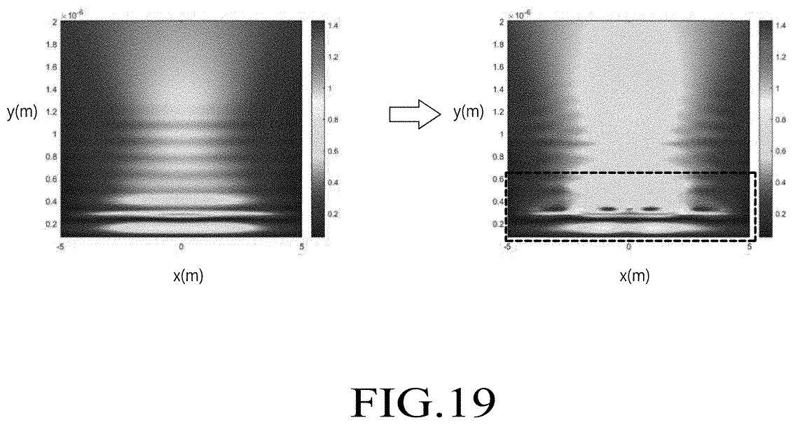

FIG. 19 regards the measurement in the transverse magnetic (TM) mode among the propagation modes. It may be identified that, in the area which had weak emission before the plurality of nano-structures were formed, after the plurality of nano-structures are formed, the light SPP which otherwise does not exit to outside due to, e.g., total reflection at the interface between the light emitting element electrodes is effectively extracted upward.

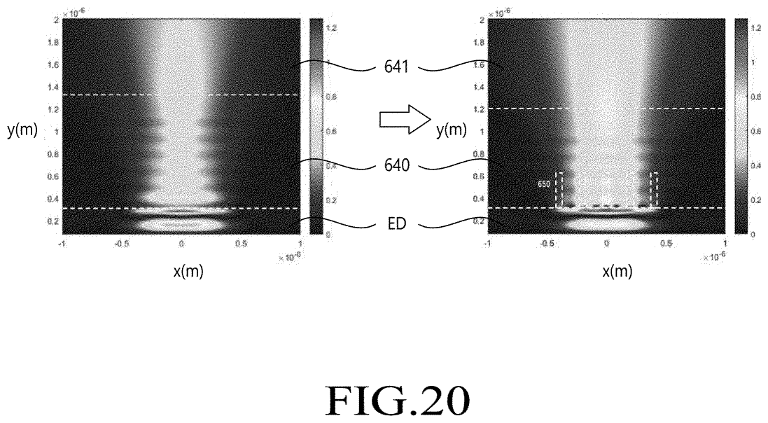

FIG. 20 regards the measurement in the transverse electromagnetic (TEM) among the propagation modes. It may be identified that the WG and/or SPP light which was otherwise trapped inside the light emitting element ED is front extracted up to the first inorganic layer 640 and the first organic layer 641 by the plurality of nano-structures.

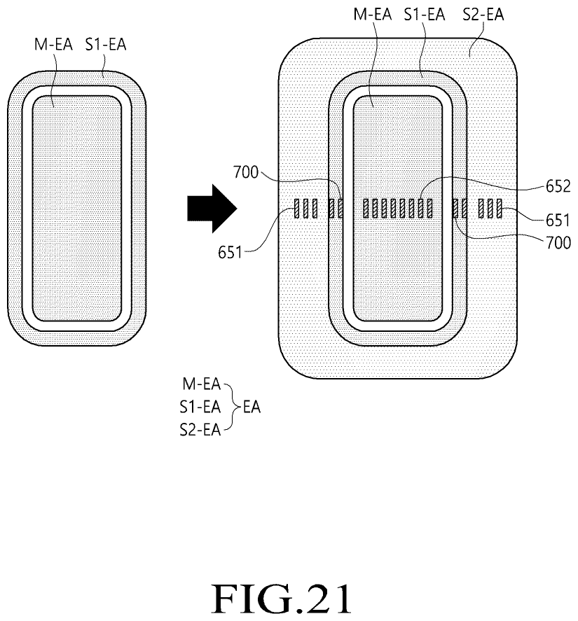

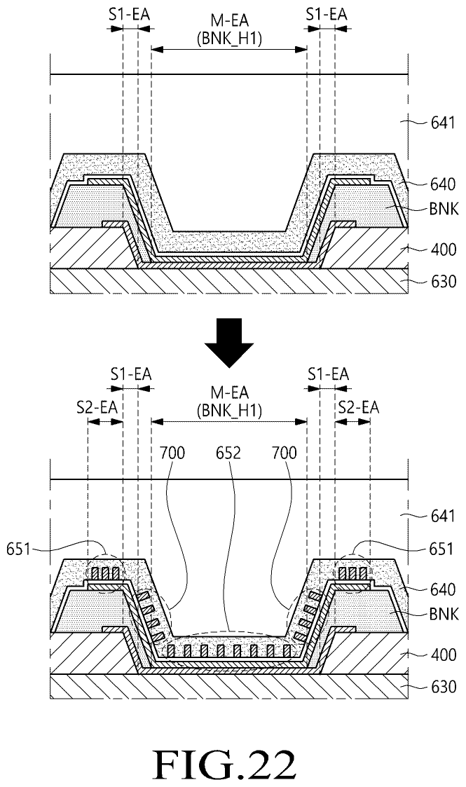

FIG. 21 is a plan view illustrating an emission area of a display panel before and after a plurality of nano-structures are formed according to implementations of the disclosure. FIG. 22 is a cross-sectional view illustrating an emission area of a display panel before and after a plurality of nano-structures are formed according to implementations of the disclosure.

Referring to FIGS. 21 and 22, the emission area EA of the first subpixel of the display panel according to implementations of the disclosure may include a main emission area M-EA, a first sub emission area S1-EA, and a second sub emission area S2-EA by forming a plurality of nano-structures, but the disclosure is not limited thereto.

For example, the main emission area M-EA may correspond to the first hole BNK_H1, and a plurality of second nano-structures 652 may be positioned inside the first hole BNK_H1, but the disclosure is not limited thereto.

For example, the first sub emission area S1-EA may correspond to the area where a plurality of third nano-structures 700 disposed on the inclined side of the bank BNK are positioned, but the disclosure is not limited thereto.

For example, the second sub emission area S2-EA may correspond to the area where a plurality of first nano-structures 651 are positioned, but the disclosure is not limited thereto. The plurality of first nano-structures 651 may be formed on the common electrode on the upper surface of the bank BNK, but the disclosure is not limited thereto.

For example, in the emission area of the light emitting element in the structure without a plurality of nano-structures, the first sub emission area S1-EA and the main emission area M-EA where the pixel electrode, the light emitting layer, and the common electrode overlap are formed as the emission area but, in the structure according to implementations of the disclosure, as the plurality of nano-structures 651, 652, and 700 are formed on the common electrode, some light that would otherwise be trapped inside the light emitting element may be extracted, so that the second sub emission area S2-EA may further be included, thereby extending the emission area EA. However, the disclosure is not limited thereto.

At least one nano-structure can be disposed in the main emission area M-EA, wherein the main emission area M-EA can overlap with the opening of the bank. For example, the opening of the bank can be a first hole BNK_H1 or a second hole BNK_H2.

At least one nano-structure may be further disposed in the first sub emission area S1-EA. Where in, the first sub emission area S1-EA may overlap with the inclined side surface of the bank BNK.

At least one nano-structure may be further disposed in the second sub emission area S2-EA. Where in, the second sub emission area S2-EA can overlap the upper surface of the bank BNK.

For example, as illustrated in FIG. 21, the main emission area M-EA, the first sub emission area S1-EA, and the second sub emission area S2-EA may be areas that constitute an emission area of a one sub pixel. In other words, a one sub pixel area may be considered to include the main emission area M-EA, the first sub emission area S1-EA, and the second sub emission area S2-EA. In this case, the first sub emission area S1-EA and the second sub emission area S2-EA may be surrounding areas of the main emission area M-EA.

As another example, one sub pixel area may include a main emission area M-EA, while the first sub-emission area S1-EA and the second sub-emission area S2-EA, which are surrounding areas of the main emission area M-EA, may be considered as surrounding areas of the sub pixel area.

A display device according to an implementation of the disclosure may be described as follows.

A display device according to implementations of the disclosure may comprise a substrate, a first planarization layer disposed on the substrate, a second planarization layer disposed on the first planarization layer and having a first opening, a first pixel electrode positioned in a first subpixel among a plurality of subpixels, disposed on the first planarization layer in the first opening, and extending along a side surface of the second planarization layer, a bank disposed on the first pixel electrode, having an upper surface and an inclined side surface, overlapping a portion of the first pixel electrode and the first opening, and including a first hole having a smaller size than the first opening, a first light emitting layer disposed on the first pixel electrode, a common electrode disposed on the first light emitting layer and extending onto the bank, and a plurality of nano-structures positioned in a first subpixel area of the first subpixel or a surrounding area of the first subpixel and disposed on the common electrode.

The plurality of nano-structures may include a plurality of first nano-structures positioned on an upper surface of the bank.

The first pixel electrode may have an inclined surface extending along a side surface of the second planarization layer. At least one of the plurality of first nano-structures may transmit light reflected from the inclined surface.

An emission area of the first subpixel may include a main emission area corresponding to the first hole, a first sub emission area corresponding to the inclined side surface of the bank, and a second sub emission area corresponding to an area where the plurality of first nano-structures are positioned.

The plurality of nano-structures may include a plurality of second nano-structures positioned inside the first hole.

The plurality of nano-structures may include a plurality of third nano-structures positioned on the inclined side surface of the bank.

The display device may further comprise an encapsulation layer on the plurality of nano-structures. The plurality of nano-structures and the encapsulation layer may include different refractive indices.

The refractive index of the plurality of nano-structures may be lower than the refractive index of the encapsulation layer.

A rear surface of at least one nano-structure among the plurality of nano-structures may have a different size from a rear surface of another nano-structure.

The rear surface of the at least one nano-structure may be larger than the rear surface of the other nano-structure. An amount of light passing through the at least one nano-structure may be larger than an amount of light passing through the other nano-structure.

The display device may further comprise a second pixel electrode positioned in a second subpixel adjacent to the first subpixel among the plurality of subpixels, disposed on the first planarization layer in a second opening of the second planarization layer, and extending along a side surface of the second planarization layer around the second opening, and a second light emitting layer disposed on the second pixel electrode. The bank may be disposed on the second pixel electrode, have an upper surface and an inclined side surface, and have a second hole overlapping a portion of the second pixel electrode. The second hole may overlap the second opening and have a size smaller than the second opening. The common electrode may be disposed on the second light emitting layer and extends onto the bank around the second hole. The plurality of nano-structures may be further disposed on the common electrode in a second subpixel area of the second subpixel or a surrounding area of the second subpixel.

The display device may further comprise a dam positioned between the first subpixel and the second subpixel and disposed on the second planarization layer.

The bank may have a third hole between the first hole and the second hole. The dam may be positioned inside the third hole.

The dam may include a material of the bank.

A height of the dam may be larger than or equal to a height of the bank.

A display device according to implementations of the disclosure may comprise a substrate, a first planarization layer disposed on the substrate, a second planarization layer disposed on the first planarization layer and having a first opening, a first pixel electrode positioned in a first subpixel among a plurality of subpixels, disposed on the first planarization layer in the first opening, and extending along a side surface of the second planarization layer, a bank disposed on the first pixel electrode, having an upper surface and an inclined side surface, overlapping a portion of the first pixel electrode and the first opening, and including a first hole having a smaller size than the first opening, a first light emitting layer disposed on the first pixel electrode, a common electrode disposed on the first light emitting layer and extending onto the bank, and a plurality of first nano-structures positioned in an area of the first subpixel or a surrounding area of the first subpixel and positioned on an upper surface of the bank. An emission area of the first subpixel may include a main emission area corresponding to the first hole, a first sub emission area corresponding to the inclined side surface of the bank, and a second sub emission area corresponding to the plurality of first nano-structures.

The first pixel electrode may have an inclined surface extending along a side surface of the second planarization layer. At least one of the plurality of first nano-structures may transmit light reflected from the inclined surface.

The plurality of first nano-structures may be formed on the common electrode.

The display device may further comprise a plurality of second nano-structures positioned inside the first hole. The plurality of second nano-structures may be positioned in the main emission area.

The display device may further comprise a plurality of third nano-structures positioned on the inclined side surface of the bank. The plurality of third nano-structures may be positioned in the first sub emission area.

The display device may further comprise a dam positioned on a side surface of the plurality of first nano-structures.

The above description has been presented to enable any person skilled in the art to make and use the technical idea of the disclosure, and has been provided in the context of a particular application and its requirements. Various modifications, additions and substitutions to the described implementations will be readily apparent to those skilled in the art, and the general principles defined herein may be applied to other implementations and applications without departing from the spirit and scope of the disclosure. The above description and the accompanying drawings provide an example of the technical idea of the disclosure for illustrative purposes only. That is, the disclosed implementations are intended to illustrate the scope of the technical idea of the disclosure.

What is claimed:

1. A display device, comprising:
a substrate;
a first planarization layer disposed on the substrate;
a second planarization layer disposed on the first planarization layer and having a first opening;
a first pixel electrode positioned in a first subpixel among a plurality of subpixels, disposed on the first planarization layer in the first opening, and extending along a side surface of the second planarization layer;
a bank disposed on the first pixel electrode, having an upper surface and an inclined side surface, overlapping a portion of the first pixel electrode and the first opening, and including a first hole having a smaller size than the first opening;
a first light emitting layer disposed on the first pixel electrode;
a common electrode disposed on the first light emitting layer and extending onto the bank; and
a plurality of nano-structures positioned in a first subpixel area of the first subpixel or a surrounding area of the first subpixel and disposed on the common electrode.

2. The display device of claim 1, wherein the plurality of nano-structures include a plurality of first nano-structures positioned on an upper surface of the bank.

3. The display device of claim 2, wherein the first pixel electrode has an inclined surface extending along a side surface of the second planarization layer, and
wherein at least one of the plurality of first nano-structures transmits light reflected from the inclined surface.

4. The display device of claim 2, wherein an emission area of the first subpixel includes:
a main emission area corresponding to the first hole;
a first sub emission area corresponding to the inclined side surface of the bank; and
a second sub emission area corresponding to an area where the plurality of first nano-structures are positioned.

5. The display device of claim 1, wherein the plurality of nano-structures include a plurality of second nano-structures positioned inside the first hole.

6. The display device of claim 1, wherein the plurality of nano-structures include a plurality of third nano-structures positioned on the inclined side surface of the bank.

7. The display device of claim 1, further comprising an encapsulation layer on the plurality of nano-structures,
wherein the plurality of nano-structures and the encapsulation layer include different refractive indices.

8. The display device of claim 7, wherein the refractive index of the plurality of nano-structures is lower than the refractive index of the encapsulation layer.

9. The display device of claim 1, wherein a rear surface of at least one nano-structure among the plurality of nano-structures has a different size from a rear surface of another nano-structure.

10. The display device of claim 9, wherein the rear surface of the at least one nano-structure is larger than the rear surface of the other nano-structure, and
wherein an amount of light passing through the at least one nano-structure is larger than an amount of light passing through the other nano-structure.

11. The display device of claim 1, further comprising:
a second pixel electrode positioned in a second subpixel adjacent to the first subpixel among the plurality of subpixels, disposed on the first planarization layer in a second opening of the second planarization layer, and extending along a side surface of the second planarization layer around the second opening; and
a second light emitting layer disposed on the second pixel electrode,
wherein the bank is disposed on the second pixel electrode, has an upper surface and an inclined side surface, and has a second hole overlapping a portion of the second pixel electrode,
wherein the second hole overlaps the second opening and has a size smaller than the second opening,
wherein the common electrode is disposed on the second light emitting layer and extends onto the bank around the second hole, and
wherein the plurality of nano-structures are further disposed on the common electrode in a second subpixel area of the second subpixel or a surrounding area of the second subpixel.

12. The display device of claim 11, further comprising a dam positioned between the first subpixel and the second subpixel and disposed on the second planarization layer.

13. The display device of claim 12, wherein the bank has a third hole between the first hole and the second hole, and
wherein the dam is positioned inside the third hole.

14. The display device of claim 13, wherein the dam includes a material of the bank.

15. The display device of claim 13, wherein a height of the dam is larger than or equal to a height of the bank.

16. A display device, comprising:
a substrate;
a first planarization layer disposed on the substrate;
a second planarization layer disposed on the first planarization layer and having a first opening;
a first pixel electrode positioned in a first subpixel among a plurality of subpixels, disposed on the first planarization layer in the first opening, and extending along a side surface of the second planarization layer;
a bank disposed on the first pixel electrode, having an upper surface and an inclined side surface, overlapping a portion of the first pixel electrode and the first opening, and including a first hole having a smaller size than the first opening;
a first light emitting layer disposed on the first pixel electrode;
a common electrode disposed on the first light emitting layer and extending onto the bank; and
a plurality of first nano-structures positioned in a first subpixel area of the first subpixel or a surrounding area of the first subpixel and positioned on an upper surface of the bank, wherein an emission area of the first subpixel includes:
a main emission area corresponding to the first hole;
a first sub emission area corresponding to the inclined side surface of the bank; and
a second sub emission area corresponding to the plurality of first nano-structures.

17. The display device of claim 16, wherein the first pixel electrode has an inclined surface extending along a side surface of the second planarization layer, and
wherein at least one of the plurality of first nano-structures transmits light reflected from the inclined surface.

18. The display device of claim 16, wherein the plurality of first nano-structures are formed on the common electrode.

19. The display device of claim 16, further comprising a plurality of second nano-structures positioned inside the first hole,
wherein the plurality of second nano-structures are positioned in the main emission area.

20. The display device of claim 16, further comprising a plurality of third nano-structures positioned on the inclined side surface of the bank,
wherein the plurality of third nano-structures are positioned in the first sub emission area.
